(19) United States
(12) Patent Application Publication
(10) Pub. No.: US 2002/0117655 A1
(43) Pub. Date: Aug. 29, 2002

(54) Quartz crystal unit and method for fabricating same

(75) Inventors: Masahiro Yoshimatsu, Saitama (JP); Mitoshi Umeki, Saitama (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: NIHON DEMPA KOGYO CO., LTD., Tokyo (JP)

(21) Appl. No.: 10/083,380

(22) Filed: Feb. 27, 2002

(30) Foreign Application Priority Data
Feb. 28, 2001 (JP) 2001-055011

(51) Int. Cl. H01L 47/00

(52) U.S. Cl. 257/1

(57) ABSTRACT

A crystal blank for use as a vibrator and a reinforcing plate are joined by direct bonding without an interposed adhesive to form a quartz crystal unit. Through-holes are provided in the reinforcing plate by etching with hydrofluoric acid. Excitation electrodes are formed on both major surfaces of the quartz crystal blank corresponding to the through-holes. An AT-cut quartz crystal plate is preferably used as the crystal blank. The reinforcing plate may be, for example, a Z-cut quartz crystal plate, an AT-cut quartz crystal plate, or a glass plate.

### BACKGROUND OF THE INVENTION

1. Field of the Invention

The present invention relates to a quartz crystal unit for high frequencies and to a method of fabricating the crystal unit, and more particularly to a quartz crystal unit in which a quartz crystal blank for use as a vibrator is adhered to a reinforcing member.

2. Description of the Related Art

Quartz crystal units are frequently used as vibrators as the reference source of frequency and time or as filter elements in various types of electronic equipment that include communication devices. There are several types of cuts from a quartz crystal according to the orientation of cutting, but an AT-cut quartz crystal which corresponds to a thickness-shear vibration mode is typically used. With the trend in recent years toward higher frequencies, such as communication frequencies, crystal blanks in AT-cut crystal units are now being processed to very thin dimensions. Generally, when using an AT-cut crystal blank, the vibration frequency of the crystal unit varies in inverse proportion to the thickness of the crystal blank, the oscillation frequency increasing with smaller thickness. When the oscillation frequency is 100 MHz, the thickness of the crystal blank is approximately 17 μm. A crystal blank that is used in a crystal unit for use at high frequencies is therefore extremely thin, and in Japanese Patent Laid-open No. 3-139912 (JP, 01139912, A), a device is disclosed in which a reinforcing plate is provided to increase the strength of the crystal blank.

We now refer to FIG. 1, in which is shown an exploded perspective view of a crystal unit of the prior art that includes a reinforcing plate, while FIG. 2 shows a vertical section of this crystal unit.

In this crystal unit, crystal blank 11 for a vibrator composed of an AT-cut quartz crystal plate and reinforcing plate 12 composed of an AT-cut crystal plate are adhered together. Excitation electrode 13A and extending electrode 14A that extends from excitation electrode 13A are formed on one major surface of crystal blank 11. In the following description, the major surface of crystal blank 11 to which reinforcing plate 12 is not bonded is referred to as the first major surface, and the major surface to which reinforcing plate 12 is bonded is referred to as the second major surface. Extending electrodes 14A and 14B are used for electrically connecting this crystal unit to, for example, an oscillation circuit. In FIG. 1, excitation electrode 13A and extending electrode 14A are depicted as having been formed on the first major surface in advance, but as will be explained hereinbelow, excitation electrode 13A and extending electrode 14A are formed in the final fabrication process of the crystal unit.

Reinforcing plate 12 is a structure in which main body 16 having a through-hole 15 is formed as a unit with electrode plate 17 for excitation. Excitation electrode 13B and extending electrode 14B that extends from excitation electrode 13B are formed on the major surface of electrode plate 17 that confronts crystal blank 11. Through-hole 15 is formed somewhat larger than excitation electrodes 13A and 13B. Excitation electrode 13B on electrode plate 17 together with excitation electrode 13A on the first major surface of crystal blank 11 are provided for exciting crystal blank 11. In other words, this crystal unit is an air-gap excitation type in which an excitation electrode is not formed on the second major surface of crystal blank 11, and crystal blank 11 is excited by means of the space field that extends from excitation electrode 13B that is positioned at a distance of the thickness of main body 16 of reinforcing plate 12.

Explanation next regards the steps for fabricating this type of crystal unit. Electrode plate 17, on which excitation electrode 13B and extending electrode 14B are formed, is first adhered by means of an adhesive to main body 16 in which through-hole 15 has been formed to form reinforcing plate 12. The open side of reinforcing plate 12 is next bonded by means of an adhesive to the second major surface of crystal blank 11. The first major surface of crystal blank 11 is next polished to produce crystal blank 11 of the stipulated thickness. Finally, excitation electrode 13A and extending electrode 14A are provided on the first major surface of crystal blank 11 to complete the crystal unit.

In this type of crystal unit, crystal blank 11 is polished as a single unit with reinforcing plate 12, and crystal blank 11 is therefore easier to handle than in a case in which crystal blank 11 is used independently, and damage to crystal blank 11 during working can be prevented. As described in the foregoing explanation, the thickness of crystal blank 11 for a vibrator must be approximately 17 μm when the oscillation frequency is 100 MHz, and the advantage of using reinforcing plate 12 therefore increases as the oscillation frequency increases.

However, a quartz crystal unit of the above-described constitution is fundamentally a three-layer structure that is bonded by means of an adhesive, and this constitution entails the problems of the potential of insufficient bonding strength and complex fabrication steps.

Japanese Patent Laid-open No. 49-90497 (JP, 49090497, A) discloses a crystal unit in which, as shown in FIG. 3, a metal or nonmetallic material is deposited by plating or evaporation on one major surface of crystal blank 11 for a vibrator, both major surfaces are polished, following which the metal or nonmetallic material of the central portion is removed by etching to form reinforcing layer 18 in the circumferential portion. Excitation electrodes 13 are formed on both major surfaces of crystal blank 11 in the central portion, and extending electrodes 14 extend from each of excitation electrodes 13. In this method, however, reinforcing layer 18 is provided by plating or evaporation, and the problem therefore exists that the bonding strength between reinforcing layer 18 and crystal blank 11 is weak. A weak bonding strength complicates the work of reducing the thickness of crystal blank 11 by, for example, polishing.

Yet another method has been proposed in which one or both of the major surfaces of a quartz crystal plate are etched to form a vibration area. In such a construction, however, although the vibration frequency is determined by the thickness of the vibration area, the formation of the vibration area by etching detracts from the flatness and parallelism of the vibration area and results in such problems as the failure to obtain the desired oscillation frequency, increased spurious vibration, and a deterioration in frequency stability.

### SUMMARY OF THE INVENTION

It is a first object of the present invention to provide a crystal unit in which productivity is improved, bonding strength is increased, and fabrication is facilitated.

It is a second object of the present invention to provide a fabrication method of a crystal unit that improves productivity, increases bonding strength, and facilitates fabrication.

The first object of the present invention is achieved by a crystal unit that includes a crystal blank for a vibrator and a reinforcing plate having a through-hole in which the crystal blank and reinforcing plate are joined by direct bonding.

In a preferable example of the present invention, the crystal blank is made from an AT-cut quartz crystal plate, and the reinforcing plate is made from a Z-cut quartz crystal plate. The use of this combination of a crystal blank and reinforcing plate affords an increase in etching speed and an improvement in productivity when the through-hole is formed in the reinforcing plate by, for example, hydrofluoric acid, that is, an aqueous solution of hydrogen fluoride.

In another preferable example of the present invention, the crystal blank is composed of an AT-cut quartz crystal plate and the reinforcing plate is composed of an AT-cut quartz crystal plate. When this combination of a crystal blank and reinforcing plate is used, each extending electrode can be led out on, of the side surface of the through-hole, an inclined surface that is oblique to a crystallographic Z′ axis of the quartz crystal that constitutes the reinforcing plate, and breaks in the extending electrode can thus be prevented.

In yet another preferable example of the present invention, the crystal blank is composed of an AT-cut quartz crystal plate and the reinforcing plate is composed of a glass plate. The use of glass plate enables the formation of isotropic inclined surfaces when forming a through-hole by etching, enables the extending electrode to be led out on an inclined surface, and can therefore prevent breaks in the extending electrodes.

The second object of the present invention is achieved by means of a fabrication method that includes the steps of: providing a through-hole corresponding to the location of formation of each crystal unit on a first wafer that corresponds to a plurality of crystal units; directly bonding the first wafer in which through-holes have been formed to a second wafer that is constituted by a quartz crystal plate to obtain a laminate; and forming excitation electrodes that are provided on both major surfaces of the second wafer corresponding to the formation location of each crystal unit, and extending electrodes that extend out from excitation electrodes, respectively, and dividing the laminate into individual crystal units.

The second object of the present invention is also achieved by a method of fabricating a crystal unit that includes the steps of: directly bonding a first wafer that corresponds to a plurality of crystal units to a second wafer that is constituted by a quartz crystal plate to obtain a laminate; forming holes that correspond to the formation location of each of the crystal units in the laminate from the major surface of the first wafer that is exposed as far as the interface of the first wafer and the second wafer; forming excitation electrodes that are provided on both major surfaces of the second wafer corresponding to the formation location of each crystal unit and extending electrodes that extend away from the excitation electrodes, respectively; and dividing the laminate into individual crystal units.

### BRIEF DESCRIPTION OF THE DRAWINGS

FIG. 1 is an exploded perspective view showing a crystal unit of the prior art;

FIG. 2 is a sectional view of the crystal unit shown in FIG. 1;

FIG. 3 is a sectional view of a crystal blank for a vibrator of the prior art;

FIG. 4 is an exploded perspective view of a crystal unit according to the first embodiment of the present invention;

FIG. 5 is a sectional view of the crystal unit that is shown in FIG. 4;

FIG. 6 shows the orientation of cutting an AT-cut quartz crystal plate;

FIG. 7 shows the orientation of cutting a Z-cut quartz crystal plate;

FIG. 8 is a partial cut-away plan view for explaining the bonding of the vibrator quartz crystal wafer and the reinforcing quartz crystal wafer in the first embodiment;

FIGS. 9A and 9B are schematic views for explaining the direct bonding in the first embodiment;

FIG. 10 is a perspective view showing a reinforcing plate in the second embodiment of the present invention;

FIG. 11 is a sectional view showing a crystal unit according to the second embodiment of the present invention; and

FIG. 12 is a sectional view showing a crystal unit according to the third embodiment of the present invention.

### DETAILED DESCRIPTION OF THE PREFERRED EMBODIMENTS

First Embodiment:

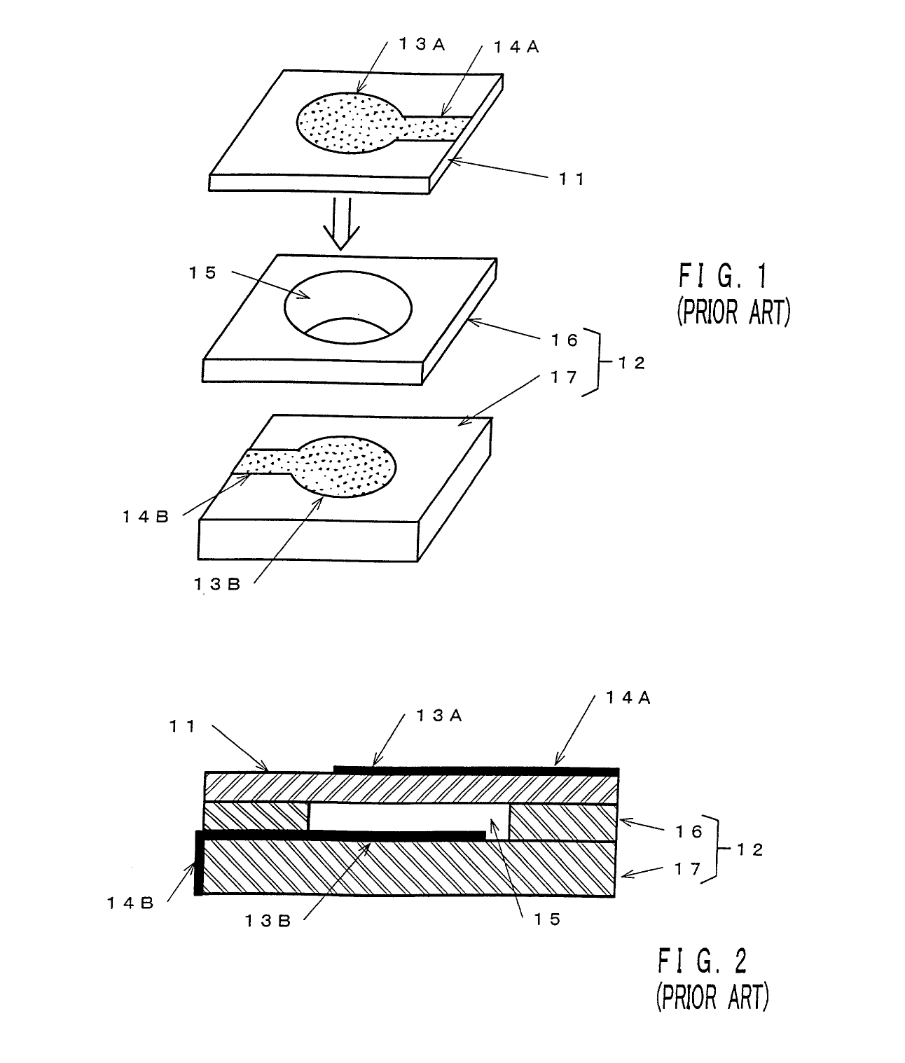

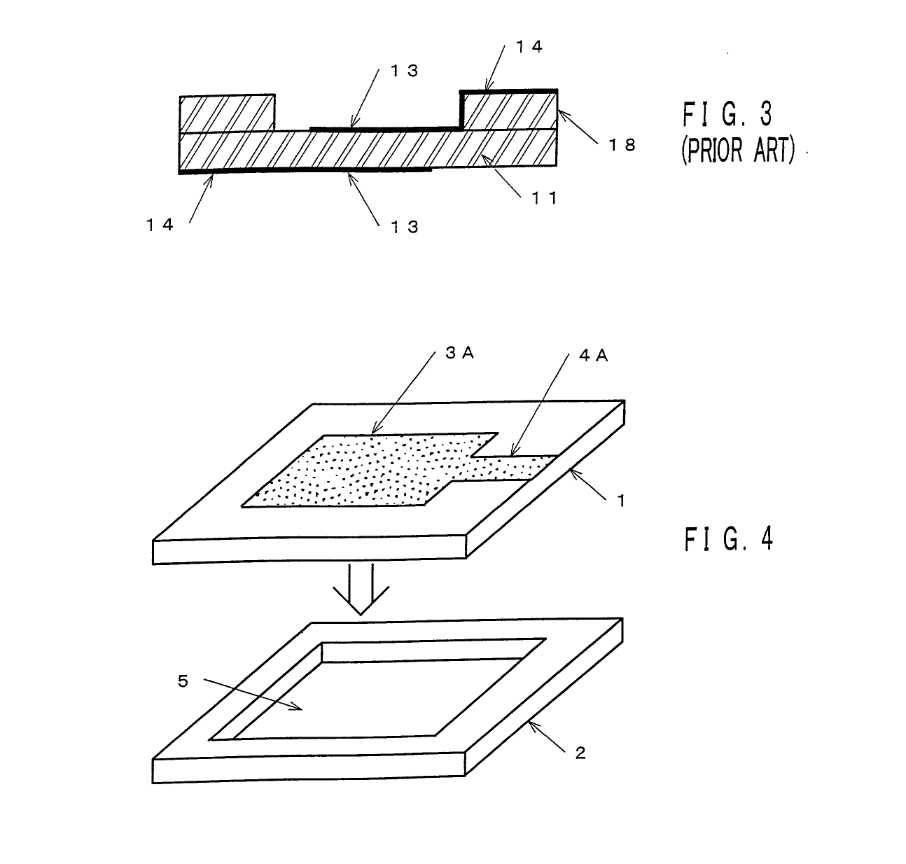

As with the crystal unit shown in FIG. 1, the crystal unit according to the first embodiment of the present invention that is shown in FIG. 4 is formed by bonding crystal blank 1 for a vibrator with reinforcing plate 2. The crystal unit shown in FIG. 4, however, differs from the crystal unit shown in FIG. 1 in that direct bonding is used without using an adhesive in bonding crystal blank 1 and reinforcing plate 2, a Z-cut quartz crystal plate is used for reinforcing plate 2, and an electrode plate for excitation is not included on reinforcing plate 2. The crystal unit of this embodiment is next explained in detail.

The crystal unit is rectangular and is realized by directly joining AT-cut quartz crystal blank 1 for a vibrator and reinforcing plate 2 that is constituted by a Z-cut quartz crystal plate. Of the two major surfaces of crystal blank 1, the major surface that is not joined to reinforcing plate 2 is referred to as the “first major surface,” and the major surface that is joined to reinforcing plate 2 is referred to as the “second major surface.” An approximately rectangular excitation electrode 3A and extending electrode 4A that extends away from excitation electrode 3A are formed on the first major surface of crystal blank 1. Rectangular through-hole 5 that is slightly larger than excitation electrode 3A is provided on reinforcing plate 2, and approximately rectangular excitation electrode 3B is formed at a position on the second major surface of crystal blank 1 that is the bottom surface of through-hole 5 so as to correspond to excitation electrode 3A. Extending electrode 4B also extends away from excitation electrode 3B, but this extending electrode 4B extends over the side wall of through-hole 5 toward the lower surface of reinforcing plate 2 as shown in the figure. In FIG. 4, excitation electrode 3A and extending electrode 4A are represented as having been formed on the first major surface in advance, but as will be explained hereinbelow, excitation electrode 3A and extending electrode 4A are formed after joining crystal blank 1 and reinforcing plate 2.

Next, regarding the AT-cut and Z-cut, the crystallographic axes (X, Y and Z axes) in a quartz crystal are uniquely defined. In the present embodiment, an AT-cut quartz crystal plate is used as crystal blank 1. As shown in FIG. 6, an AT-cut quartz crystal plate is a quartz crystal plate that is cut with the major surface (the YZ plane) inclined 35.15° with respect to the Y-axis in a direction from the Z-axis toward the Y-axis with the X-axis as center. In other words, in this quartz crystal plate, the normal to the major surface is inclined 35.15° in the direction of the Z-axis from the Y-axis. The new inclined axes are the Y′-axis and the Z′-axis. The Y′-axis is aligned with the normal to the major surface of the AT-cut quartz crystal plate, and the Z′-axis is aligned within the surface of this quartz crystal plate.

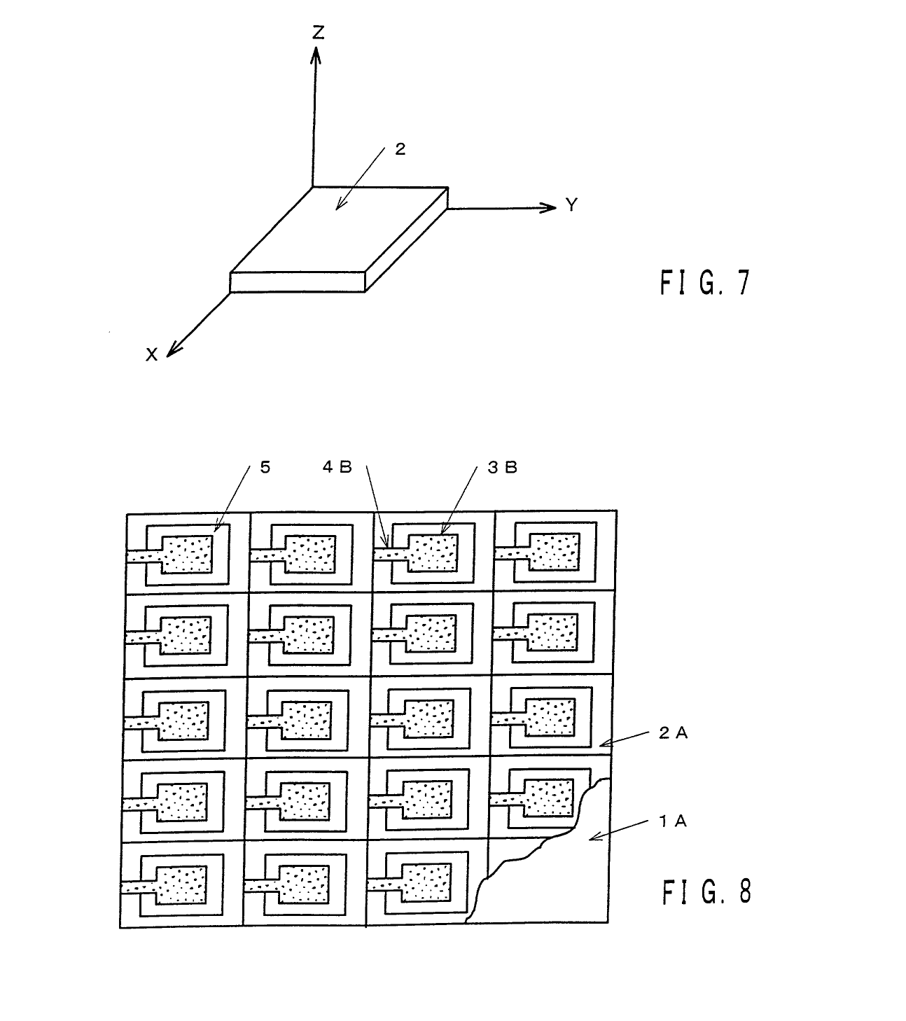

In contrast, a Z-cut quartz crystal plate is used as reinforcing plate 2. A Z-cut quartz crystal plate is a quartz crystal plate that has been cut with the major surface as the XY plane as shown in FIG. 7. In other words, a Z-cut quartz crystal plate is a quartz crystal plate that has been cut such that the cutting plane is perpendicular to the Z-axis of the quartz crystal.

Explanation next regards the fabrication steps for this quartz crystal unit.

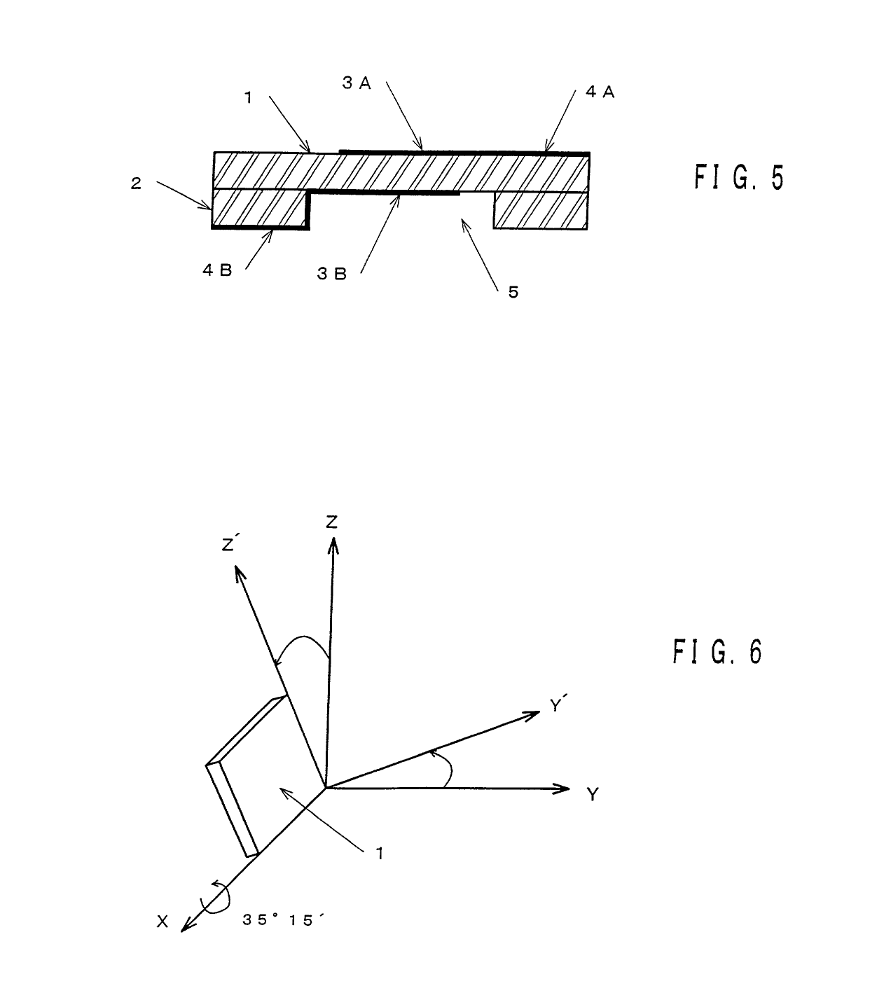

Although crystal blanks 1 and reinforcing plates 2 may be joined one at a time in the crystal unit of this embodiment, this approach is not amenable to mass production. A fabrication process in which a plurality of crystal units are simultaneously fabricated is therefore described with reference to FIG. 8. In the following explanation, the quartz crystal plate that is used for simultaneously fabricating a plurality of crystal units is referred to as a quartz crystal wafer. In the case shown in FIG. 8, twenty (=4×5) crystal units can be fabricated at the same time. It should be noted that the vertical relationship between crystal blanks 1 and reinforcing plates 2 in FIG. 8 is the reverse of the relationship shown in FIGS. 4 and 5.

Quartz crystal wafer 1A that has been AT-cut as the component corresponding to crystal plate 1 and wafer 2A that has been Z-cut as the component corresponding to reinforcing plate 2 are first directly bonded. A plurality of through-holes 5 has been formed in advance in quartz crystal wafer 2A by etching with hydrofluoric acid. When etching, only the areas that are to become through-holes 5 on one major surface of quartz crystal wafer 2A are exposed and the other areas are covered by a masking material.

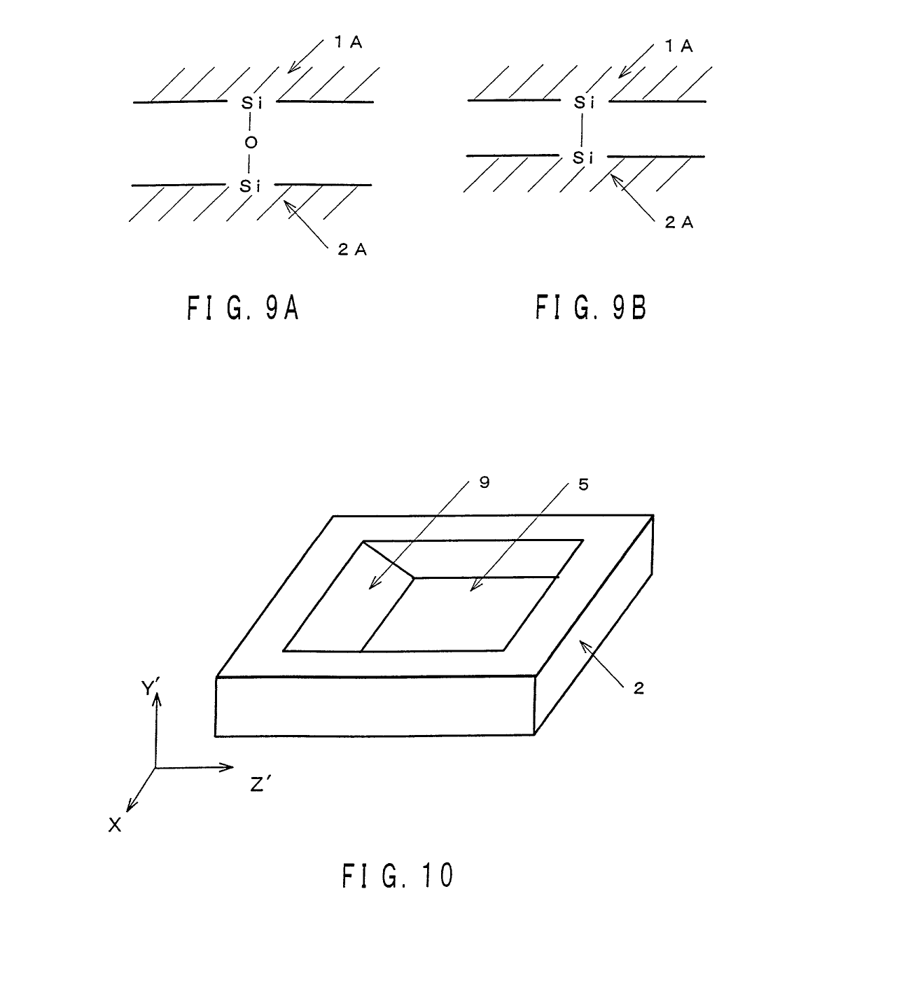

When directly bonding the wafers, the major surfaces of both vibrator quartz crystal wafer 1A and reinforcing-plate quartz crystal wafer 2A are first given a mirror polish, and the polished surfaces are further processed to have a hydrophilic property. The process for giving the surface a hydrophilic property is a chemical process such that the surface of the quartz crystal wafer is modified by a hydrophilic group, typically the —OH group (hydroxyl group). This type of chemical process is well known by those in the art, but as an example, the surface of the quartz crystal wafer can be made hydrophilic by means of cleaning that follows mirror polishing. The major surfaces of quartz crystal wafers 1A and 2A are then placed against each other and subjected to a heating process, whereby an H₂O (water) molecule is extracted from the hydroxyl groups of both major surfaces by means of a dehydration reaction to form an Si—O—Si bond, i.e., a siloxane bond. Quartz crystal wafers 1A and 2A are thus securely joined together. FIG. 9A gives a schematic representation of the direct bonding of quartz crystal wafers 1A and 2A when an Si—O—Si bond is produced. As depicted in the figure, a gap exists between quartz crystal wafers 1A and 2A, and an oxygen atom of the siloxane bond is shown to exist in this gap, but the two wafers are in actuality joined in close proximity on the atomic level.

Alternatively, the surface of one of quartz crystal wafers 1A and 2A is subjected to processing to make the surface hydrophilic, and the other surface is subjected to processing to make the surface hydrophobic, following which the two major surfaces are placed against each other and subjected to a heating process. The process for producing the hydrophobic property in this case is a process that exposes a hydrophobic group, typically a hydrogen atom (—H) that is directly bonded to a silicon atom, on the surface of the quartz crystal wafer. This type of chemical process is well known to those in the field, but as an example, the surface may be processed by dilute hydrofluoric acid to substitute an —H atom for the —OH group that is present on the wafer surface such that the surface exhibits a hydrophobic property. When a hydrophilic surface is combined with a hydrophobic surface, an H₂O molecule is extracted by a heat treatment to form an Si—Si bond, whereby the two quartz crystal wafers 1A and 2A are securely joined together. FIG. 9B gives a schematic representation of the direct bonding of quartz crystal wafers 1A and 2A when Si—Si bonding takes place. Although a gap is shown between quartz crystal wafers 1A and 2A, the two wafers are in actuality joined in close proximity on the atomic level.

This type of direct bonding of quartz crystal plates is described in Japanese Patent Laid-open No. 2000-269106 (JP, A2000-269106).

Upon completion of direct bonding of quartz crystal wafers 1A and 2A, the thickness of vibrator quartz crystal wafer 1A is reduced by polishing to obtain the desired oscillation frequency. In polishing, quartz crystal wafer 1A may be polished from both major surface sides, or may be polished on only the major surface that is not directly bonded. Vibrator quartz crystal wafer 1A may be processed to a provisional thickness during the step of mirror polishing that is carried out before direct bonding, and the thickness of quartz crystal wafer 1A then reduced to the final thickness by etching using dilute hydrofluoric acid after direct bonding.

Excitation electrodes and extending electrodes are next formed by means of, for example, vacuum evaporation on both major surfaces of vibrator quartz crystal wafer 1A for each portion that is intended to be cut as a crystal unit. FIG. 8 gives a representation of the positions at which excitation electrodes 3B and extending electrodes 4B are provided on, of the major surfaces of vibrator quartz crystal wafer 1A, the major surface that is bonded to reinforcing-plate quartz crystal wafer 2A. Although not shown in this figure, excitation electrodes 3A (FIG. 5) and extending electrodes 4A (FIG. 5) are also formed on the major surface that is on the opposite side. Extending electrode 4B is provided extending over the side wall of through-hole 5 as far as the upper surface of reinforcing-plate quartz crystal wafer 2A.

Following the formation of the excitation electrodes and extending electrodes, the laminate of quartz crystal wafers 1A and 2A is divided into individual crystal units, whereby a plurality of crystal units shown in FIGS. 4 and 5 are simultaneously obtained.

In this type of quartz crystal unit, crystal blank 1 (vibrator quartz crystal wafer 1A) and reinforcing plate 2 (reinforcing-plate quartz crystal wafer 2A) are connected by means of direct bonding, and the bonding between the two wafers is therefore a chemical bond with high bonding strength. This strength facilitates handling of the quartz crystal units during fabrication, and, for example, eases the task of reducing the thickness by polishing after bonding. In addition, the two-layer structure of crystal blank 1 and reinforcing plate 2 in the present embodiment maintains the strength of the crystal unit and simplifies the fabrication steps.

In particular, the embodiment that is here explained employs a Z-cut quartz crystal plate as reinforcing plate 2 in which through-holes 5 are formed, whereby the processing time for etching to form through-holes 5 can be reduced and productivity increased. This effect can be obtained because the etching speed by hydrofluoric acid solution in each crystallographic axial direction of the quartz crystal is typically in the relation: Z-axis>>X-axis>Y-axis, the etching speed in the Z-axis direction being markedly faster than etching speed in the other crystal orientations.

Although vibrator quartz crystal wafer 1A was directly bonded to reinforcing-plate quartz crystal wafer 2A after providing through-holes 5 in quartz crystal wafer 2A in the above-described fabrication steps, through-holes 5 may be provided by etching after the two wafers have been directly bonded. In this case, if quartz crystal wafer 2A is a Z-cut quartz crystal plate and quartz crystal wafer 1A is an AT-cut quartz crystal plate, the etching time can be easily controlled in accordance with the difference in etching speeds between the two wafers to halt the etching at the interface between the two wafers. When direct bonding is carried out after providing through-holes 5 in quartz crystal wafer 2A, the existence of through-holes 5 tends to eliminate gas bubbles that occur at the interface between quartz crystal wafers 1A and 2A when carrying out direct bonding.

Second Embodiment:

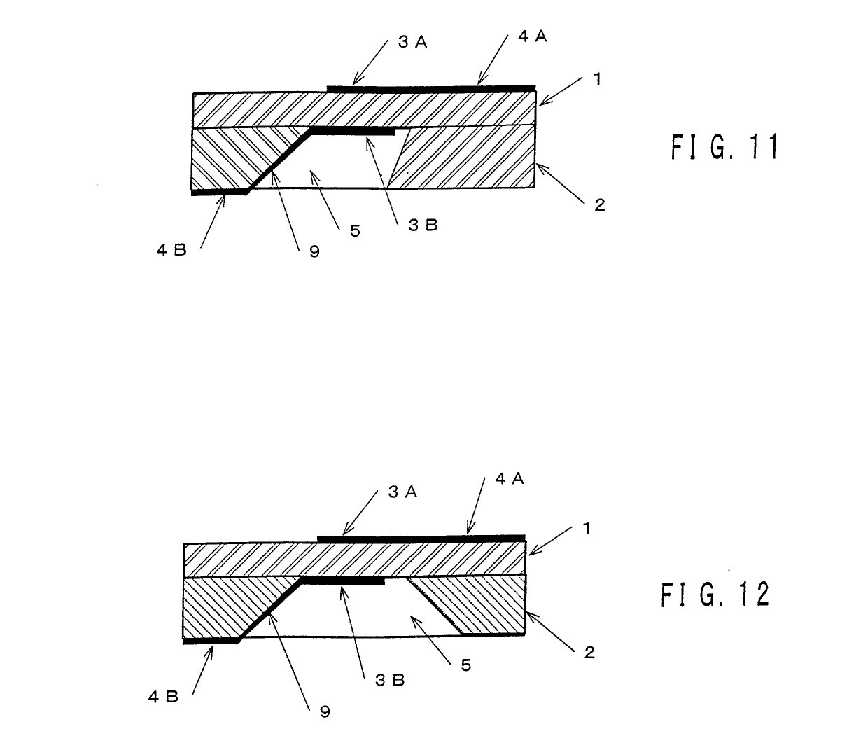

In FIGS. 10 and 11 that show a crystal unit according to the second embodiment of the present invention, constituent elements that are identical to elements in FIGS. 4 and 5 are identified by the same reference numerals and redundant explanation is not repeated.

The quartz crystal unit of this embodiment is similar to the crystal unit of the above-described first embodiment with the exception that an AT-cut quartz crystal plate is used as reinforcing plate 2. As a result of using an AT-cut quartz crystal plate, the shape of through-holes 5 that are provided by etching in reinforcing plate 2 take on a form having a slanted surface.

Explanation next regards the specifics of the shape of through-hole 5 for a case in which the longitudinal direction of the rectangular crystal unit is aligned with the Z′-axis of the quartz crystal and the direction of width is aligned with the X-axis of the quartz crystal. When forming through-hole 5, etching is carried out by means of hydrofluoric acid with the AT-cut quartz crystal plate that is used as reinforcing plate 2 being covered by a mask and only the formation locations of through-holes 5 on one of the major surfaces thereof exposed. The differences in etching speeds according to the orientation of the crystal surfaces (Z-axis>>X-axis>Y-axis) gives rise to, of the side surfaces of through-hole 5, inclined surface 9 that exposes a surface on one of the side surfaces that is in the Z′-axis direction, i.e., the longitudinal direction. This inclined surface 9 is an inclined surface that is oblique to the Z′-axis of the quartz crystal. The side surface that is opposite inclined surface 9 is hollowed out, i.e., undercut, by the etching process. In contrast, the inside surfaces in the direction of width (aligned with the X-axis) are steeply inclined surfaces that are nearly perpendicular.

In this embodiment, as is disclosed in Japanese Patent Laid-open No. 2000-228618 (JP, A2000-228618), excitation electrode 3B is formed on, of the major surfaces of quartz crystal blank 1, the major surface that is on the side of formation of through-hole 5, and extending electrode 4B that extends from this excitation electrode 3B reaches the surface of reinforcing plate 2 by crossing over inclined surface 9. Extending electrode 4B provided in this way can prevent breaks in extending electrode 4B when forming excitation electrode 3B and extending electrode 4B by vacuum evaporation.

As with the first embodiment, when fabricating a crystal unit of this embodiment, a quartz crystal wafer can be used that is of a size in which a plurality of crystal unit portions are arranged vertically and horizontally. In this case, through-holes 5 such as described hereinabove are formed in a reinforcing-plate quartz crystal wafer constituted by an AT-cut quartz crystal plate by etching in the area of each crystal unit, following which the vibrator quartz crystal wafer and the reinforcing-plate quartz crystal wafer are directly bonded. After direct bonding, the final thickness of the vibrator quartz crystal wafer is adjusted as in the first embodiment, and excitation electrodes 3A and 3B and extending electrodes 4A and 4B are formed. Finally, the laminate of the two quartz crystal wafers is divided into the individual crystal units, whereby a plurality of crystal units such as shown in FIGS. 10 and 11 can be obtained simultaneously.

In this case in particular, the excitation electrodes and extending electrodes are formed at the time that the vibrator quartz crystal wafer and the reinforcing-plate quartz crystal wafer are directly bonded, following which the individual crystal units are divided. Thus, in comparison with the formation of excitation electrodes and extending electrodes after division into individual crystal units, positioning and other steps are unnecessary because the positions of inclined surfaces 9 are arranged in a uniform direction, and the fabrication is therefore simplified.

Although the two quartz crystal wafers are directly bonded after providing through-holes 5 in reinforcing-plate quartz crystal wafer in the above-described fabrication process, through-holes 5 may be provided by etching after direct bonding of the two wafers. In this case, after direct bonding of the two wafers, the major surface of the reinforcing-plate quartz crystal wafer that is exposed is entirely covered by a mask with the exception of openings at only the formation positions of through-holes 5, and etching is carried out to form through-holes 5 of a desired depth. The mask is then removed, the thickness of the vibrator quartz crystal wafer adjusted, the excitation electrodes and extending electrodes formed, and the laminate then divided into individual crystal units.

Third Embodiment:

In FIG. 12, which shows a crystal unit according to the third embodiment of the present invention, constituent elements that are identical to elements in FIGS. 4 and 5 are identified by the same reference numerals and redundant explanation is not repeated.

The crystal unit of this embodiment is identical to the crystal unit of the above-described first embodiment with the exception that a glass plate is employed as reinforcing plate 2. As a result of using a glass plate, through-holes 5 that are provided by etching in reinforcing plate 2 all have the same inclined surface for each side surface.

Although through-holes 5 are formed in reinforcing plate 2 by etching with hydrofluoric acid in this embodiment as well, glass, in contrast to quartz crystal, allows for isotropic etching. Thus, when etching is carried out on the glass plate that is used as reinforcing plate 2 by exposing only the positions of formation of through-holes 5 on one major surface and covering all other areas by a mask, through-holes 5 are formed in a shape that tapers from one major surface of the glass plate to the other major surface. As a result, through-holes 5 are formed in a shape having inclined side surfaces as described hereinabove. In this crystal unit as well, extending electrodes 4B that extend from excitation electrodes 3B that are formed on, of the major surfaces of crystal blank 1, the major surface which is on the side of through-holes 5 are provided so as to pass over an inclined surface of through-holes 5 to reach the surface of reinforcing plate 2, and breaks in extending electrodes 4B are therefore prevented. In addition, the use of a glass plate facilitates leading out extending electrodes 4B from any direction because inclined surfaces are similarly formed in each direction.

Any type of glass plate may be employed as long as the glass plate that is used as reinforcing plate 2 in this embodiment does not exert an adverse influence on the electronic characteristics of the crystal unit and can obtain sufficient bonding strength. As examples, quartz glass, borosilicate glass, or soda glass may be used.

As in the first embodiment, when fabricating a crystal unit according to this embodiment, a quartz crystal wafer and glass plate of a size in which a plurality of crystal units are arranged horizontally and vertically may be used. In such a case, the previously described through-holes 5 are formed by etching in the area of each crystal unit on the reinforcing-plate glass plate, following which vibrator quartz crystal wafer 1A and the glass plate are directly bonded. After direct bonding, final adjustment of the thickness of vibrator quartz crystal wafer 1A is performed, and excitation electrodes 3A and 3B and extending electrodes 4A and 4B are formed. Finally, the laminate made up by quartz crystal wafer 1A and the glass plate is divided into the individual crystal units, whereby a plurality of crystal unit such as shown in FIG. 12 can be obtained simultaneously.

Although the glass plate and the quartz crystal wafer are directly bonded after forming through-holes 5 in the reinforcing-plate glass plate in the above-described fabrication process, through-holes 5 in this embodiment may also be provided by etching after directly bonding the quartz crystal wafer and glass plate. In such a case, after the direct bonding of the glass plate and quartz crystal wafer, the major surface of the glass plate that is exposed is covered with a mask leaving openings only at the locations of formation of through-holes 5, etching is carried out, and through-holes 5 of a desired depth are formed. Since the etching speed of glass plate is generally faster than that of an AT-cut quartz crystal plate, the etching speed can easily be controlled to halt etching at the interface between the glass plate and quartz crystal plate. The mask may then be removed, the thickness of the vibrator quartz crystal wafer adjusted, the excitation electrodes and extending electrodes formed, and the laminate then divided into individual crystal units.

Although preferable embodiments of the present invention have been described in the foregoing explanation, the present invention is not limited to any of the above-described embodiments. For example, the planar shape of the crystal units may be round or oval, or the shape of the through-holes may be round or oval instead of rectangular.

What is claimed is:

1. A crystal unit comprising a crystal blank for a vibrator and a reinforcing plate that includes a through-hole, said crystal blank and said reinforcing plate being joined by direct bonding.

2. A crystal unit according to claim 1, comprising:
a pair of excitation electrodes, one excitation electrode being formed on one of two major surfaces of said crystal blank, and the other excitation electrode being formed on the other major surface of said crystal blank, said excitation electrodes corresponding to location of said through-hole, and
extending electrodes that extend away from respective excitation electrodes.

3. A crystal unit according to claim 2, wherein an Si—O—Si chemical bond is formed between said crystal blank and said reinforcing plate as said direct bonding.

4. A crystal unit according to claim 2, wherein an Si—Si chemical bond is formed between said crystal blank and said reinforcing plate as said direct bonding.

5. A crystal unit according to claim 1, wherein said crystal blank is constituted by an AT-cut quartz crystal plate, and said reinforcing plate is constituted by a Z-cut quartz crystal plate.

6. A crystal unit according to claim 2, wherein said crystal blank is constituted by an AT-cut quartz crystal plate, and said reinforcing plate is constituted by a Z-cut quartz crystal plate.

7. A crystal unit according to claim 2, wherein said crystal blank is constituted by an AT-cut quartz crystal plate; said reinforcing plate is constituted by an AT-cut quartz crystal plate; and one of said extending electrodes extends over, of side surfaces of said through-hole, an inclined surface that is oblique to a crystallographic Z′-axis of a quartz crystal that constitutes said reinforcing plate.

8. A crystal unit according to claim 1, wherein said crystal blank is constituted by an AT-cut quartz crystal plate, and said reinforcing plate is constituted by a glass plate.

9. A crystal unit according to claim 2, wherein said crystal blank is constituted by an AT-cut quartz crystal plate, and said reinforcing plate is constituted by a glass plate.

10. A method of fabricating a crystal unit, comprising steps of:
providing a through-hole corresponding to a formation location of each crystal unit in a first wafer that corresponds to a plurality of said crystal units;
directly bonding said first wafer in which said through-holes have been formed to a second wafer constituted by a quartz crystal plate to obtain a laminate;
forming excitation electrodes that are provided on both major surfaces of said second wafer corresponding to the formation location of each of said crystal units, and extending electrodes that extend away from said excitation electrodes, respectively; and
dividing said laminate into individual crystal units.

11. A method of fabricating a crystal unit according to claim 10, wherein said first wafer is constituted by a Z-cut quartz crystal plate, and said second wafer is constituted by an AT-cut quartz crystal plate.

12. A method of fabricating a crystal unit according to claim 10, wherein said first wafer is constituted by an AT-cut quartz crystal plate, and said second wafer is constituted by an AT-cut quartz crystal plate.

13. A method of fabricating a crystal unit according to claim 12, wherein said extending electrode, which is connected to said excitation electrode that is formed on the major surface of said second wafer that is the through-hole side, is formed on an inclined plane that is oblique to the Z′-axis of the quartz crystal and that occurs in said through-hole.

14. A method of fabricating a crystal unit according to claim 10, wherein said first wafer is constituted by a glass plate, and said second wafer is constituted by an AT-cut quartz crystal plate.

15. A method of fabricating a crystal unit, comprising steps of:
directly bonding a first wafer that corresponds to a plurality of crystal units to a second wafer that is constituted by a quartz crystal plate to obtain a laminate;
forming holes that correspond to a formation location of each of said crystal units in said laminate from the major surface of said first wafer that is exposed as far as an interface of said first wafer and said second wafer;
forming excitation electrodes that are provided on both major surfaces of said second wafer that correspond to the formation location of each of said crystal units, and extending electrodes that extend away from excitation electrodes, respectively; and
dividing said laminate into individual crystal units.

16. A method of fabricating a crystal unit according to claim 15, wherein said first wafer is constituted by a Z-cut quartz crystal plate, and said second wafer is constituted by an AT-cut quartz crystal plate.

17. A method of fabricating a crystal unit according to claim 15, wherein said first wafer is constituted by an AT-cut quartz crystal plate, and said second wafer is constituted by an AT-cut quartz crystal plate.

18. A method of fabricating a crystal unit according to claim 17, wherein an extending electrode that is connected to said excitation electrode that is formed on the major surface of said second wafer that is the through-hole side are formed on an inclined surface that is oblique to Z′-axis of a quartz crystal and that occurs in said through-hole.

19. A method of fabricating a crystal unit according to claim 15, wherein said first wafer is constituted by a glass plate, and said second wafer is constituted by an AT-cut quartz crystal plate.
